(19) United States
(12) Patent Application Publication
(10) Pub. No.: US 2024/0290577 A1
(43) Pub. Date: Aug. 29, 2024

(54) SUBSTRATE PROCESSING APPARATUS AND SUBSTRATE PROCESSING METHOD

(71) Applicant: Tokyo Electron Limited, Tokyo (JP)

(72) Inventors: Shinya ISHIKAWA, Miyagi (JP); Shinya TAMONOKI, Miyagi (JP); Naoki MATSUMOTO, Miyagi (JP); Naoki MIHARA, Miyagi (JP); Naoki FUJIWARA, Miyagi (JP); Koichi NAGAMI, Miyagi (JP); Nozomu NAGASHIMA, Miyagi (JP); Hiroki ENDO, Miyagi (JP)

(73) Assignee: Tokyo Electron Limited, Tokyo (JP)

(21) Appl. No.: 18/660,479

(22) Filed: May 10, 2024

Related U.S. Application Data
(63) Continuation of application No. PCT/JP2022/025118, filed on Jun. 23, 2022.
(60) Provisional application No. 63/278,721, filed on Nov. 12, 2021.

(51) Int. Cl. H01J 37/32; H02M 1/15; H02M 7/219

(52) U.S. Cl. CPC H01J 37/32174; H01J 37/32091; H01J 37/32155; H02M 1/15; H02M 7/219; H01J 2237/332; H01J 2237/334

(57) ABSTRACT

A substrate processing apparatus comprises a power storage part and at least one unit or member that uses a power. Charges stored in the power storage part are supplied, as a power, to the unit or the member.

### CROSS-REFERENCE TO RELATED APPLICATIONS

This application is a bypass continuation application of International Application No. PCT/JP2022/025118 having an international filing date of Jun. 23, 2022 and designating the United States, the International Application being based upon and claiming the benefit of priority from U.S. Patent Application No. 63/278,721 filed on Nov. 12, 2021, the entire contents of each are incorporated herein by reference.

### TECHNICAL FIELD

The present disclosure relates to a substrate processing apparatus and a substrate processing method.

### BACKGROUND

Japanese Laid-open Patent Publication No. 2015-173027 discloses a plasma processing apparatus as a substrate processing apparatus. The plasma processing apparatus uses a filter to attenuate or block high-frequency noise that enters a power supply line from an electrical member other than a high-frequency electrode in a processing chamber.

### SUMMARY

The present disclosure discloses appropriate supply of a power to a substrate processing apparatus.

One embodiment of the present disclosure is a substrate processing apparatus comprising a power storage part and at least one unit or member that uses a power, wherein charges stored in the power storage part are supplied, as a power, to the unit or the member.

### BRIEF DESCRIPTION OF THE DRAWINGS

FIG. 1 explains a configuration example of a plasma processing apparatus according to an embodiment.

FIG. 2 explains a configuration example of a capacitively coupled plasma processing apparatus.

FIG. 3 is a plan view schematically showing a configuration of a substrate processing system.

FIG. 4 shows a schematic configuration of a power supply system of a plasma processing apparatus according to an embodiment.

FIGS. 5A and 5B are schematic explanatory diagrams of the arrangement relationship between a power transmitting coil and a power receiving coil.

FIGS. 6A to 6H are schematic explanatory diagrams of the opposing relationship between coils.

FIG. 7 shows a schematic configuration of a power supply system having a power supply system that can be used in one embodiment.

FIG. 8 shows a schematic configuration of a power supply system having a power supply system that can be used in one embodiment.

FIG. 9 shows a schematic configuration of another power supply system having a power supply system that can be used in one embodiment.

FIG. 10 shows a schematic configuration of another power supply system having a power supply system that can be used in one embodiment.

FIG. 11 shows a schematic configuration of another power supply system having a power supply system that can be used in one embodiment.

FIG. 12 explains a configuration example of a plasma processing apparatus of a reference example.

FIG. 13 explains a plasma processing system of a reference example.

FIG. 14 shows a schematic configuration of a power supply system having a power supply system that can be used in a reference example.

FIG. 15 shows a schematic configuration of another power supply system having a power supply system that can be used in a reference example.

### DETAILED DESCRIPTION

In a semiconductor device manufacturing process, a processing module accommodating a semiconductor substrate (hereinafter, also simply referred to as “substrate”) is depressurized, and various substrate treatments for performing predetermined processing on the substrate are performed. For example, plasma processing is performed by placing a substrate on a substrate support in a processing chamber, heating the substrate support, and producing plasma in the processing chamber using an RF power.

In the case of heating the substrate support, an alternating current (hereinafter, simply referred to as “AC”) power from an AC power source in a factory is supplied to the heater, for example. However, in the case of producing plasma in the processing chamber using an RF power and performing plasma processing, RF noise may reach the AC power source through a power supply line via the substrate support, and cause adverse effects on the operation or performance of the AC power source. Japanese Laid-open Patent Publication No. 2015-173027 discloses an RF filter that attenuates or blocks RF noise to prevent or suppress propagation of RF noise to an AC power source.

However, if a so-called RF filter that attenuates or blocks RF noise is interposed in the power supply path, the supplied power may be attenuated by the RF filter, and the expected power may not be inputted to the heater. Further, RF filters are required as many as the number of power supply targets, and a space for arranging the RF filters may not be secured in the device.

In view of the above, the present disclosure provides a technique that easily deals with a case where RF noise reaches an AC power source through a power supply path via a substrate support, for example, without using the above-described RF filter. Further, the present disclosure efficiently supplies a power to a unit and a member that uses a power in a substrate processing apparatus. Furthermore, the present disclosure can save a space in a device.

Hereinafter, a plasma processing apparatus as a substrate processing apparatus according to an embodiment of the present disclosure will be described with reference to the accompanying drawings. Like reference numerals will be used for like parts having substantially the same functional configurations throughout this specification and the drawings, and redundant description thereof will be omitted.

### <Plasma Processing System>

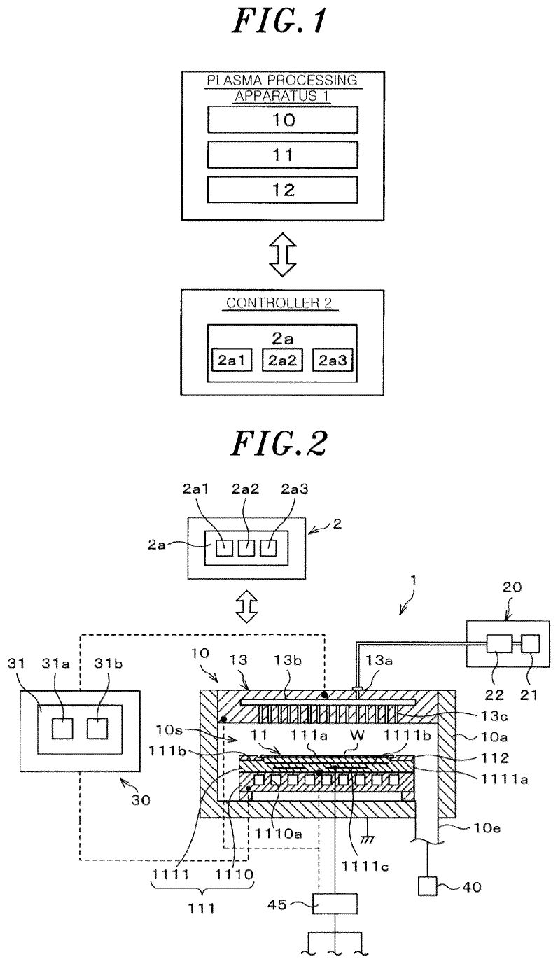

FIG. 1 shows a plasma processing system including a plasma processing apparatus 1 as an example of a substrate processing apparatus. The plasma processing system includes a plasma processing apparatus 1 and a controller 2. The plasma processing apparatus 1 includes a plasma processing chamber 10, a substrate support 11, and a plasma generator 12. The plasma processing chamber 10 has a plasma processing space. The plasma processing chamber 10 has at least one gas supply port for supplying at least one processing gas to the plasma processing space, and at least one gas exhaust port for discharging a gas from the plasma processing space. The gas supply port is connected to a gas supply part 20 to be described later, and the gas discharge port is connected to an exhaust system 40 to be described later. The substrate support 11 is disposed in the plasma processing space, and has a substrate supporting surface for supporting a substrate.

The plasma generator 12 is configured to generate plasma from at least one processing gas supplied into the plasma processing space. The plasmas generated in the plasma processing space may be capacitively coupled plasma (CCP), inductively coupled plasma (ICP), electron-cyclotron-resonance (ECR) plasma, helicon wave plasma (HWP), surface wave plasma (SWP), or the like. Further, various types of plasma generators including an alternating current (AC) plasma generator and a direct current (hereinafter, simply referred to as DC) plasma generator may be used. In one embodiment, an AC signal (AC power) used in the AC plasma generator has a frequency within a range of 100 kHz to 10 GHz. Therefore, the AC signal includes a radio frequency (RF) signal and a microwave signal. In one embodiment, the RF signal has a frequency within a range of 100 kHz to 150 MHz.

The controller 2 processes computer-executable instructions that cause the plasma processing apparatus 1 to perform various steps described in the present disclosure. The controller 2 may be configured to control individual components of the plasma processing apparatus 1 to perform various steps described herein. In one embodiment, the controller 2 may be partially or entirely included in the plasma processing apparatus 1. The controller 2 may include a processing part 2a1, a storage part 2a2, and a communication interface 2a3. The controller 2 is realized by, e.g., a computer 2a. The processing part 2a1 may be configured to read a program from the storage part 2a2 and perform various control operations by executing the read program. The program may be stored in the storage part 2a2 in advance, or may be acquired via a medium when necessary. The acquired program is stored in the storage part 2a2, and is read out from the storage part 2a2 and executed by the processing part 2a1. The medium may be various storage media that are readable by the computer 2a, or may be a communication line connected to the communication interface 2a3. The processing part 2a1 may be a central processing unit (CPU). The storage part 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN) or the like.

### <Plasma Processing Apparatus>

Hereinafter, a configuration example of a capacitively coupled plasma processing apparatus as an example of the plasma processing apparatus 1 will be described. FIG. 2 explains a configuration example of the capacitively coupled plasma processing apparatus 1.

The capacitively coupled plasma processing apparatus 1 includes the plasma processing chamber 10, the gas supply part 20, a power supply 30, and the exhaust system 40. Further, the plasma processing apparatus 1 includes the substrate support 11 and a gas introducing part. The gas introducing part is configured to introduce at least one processing gas into the plasma processing chamber 10. The gas introducing part includes a shower head 13. The substrate support 11 is disposed in the plasma processing chamber 10. The shower head 13 is disposed above the substrate support 11. In one embodiment, the shower head 13 forms at least a part of the ceiling of plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a main body 111 and a ring assembly 112. The main body 111 has a central region 111a for supporting the substrate W and an annular region 111b for supporting the ring assembly 112. The annular region 111b of the main body 111 surrounds the central region 111a of the main body 111 in plan view. The substrate W is placed on the central region 111a of the main body 111, and the ring assembly 112 is placed on the annular region 111b of the main body 111 to surround the substrate W on the central region 111a of the main body 111. Therefore, the central region 111a is also referred to as a substrate supporting surface for supporting the substrate W and the annular region 111b is also referred to as a ring supporting surface for supporting the ring assembly 112.

In one embodiment, the main body 111 includes a base 1110 and an electrostatic chuck 1111. The base 1110 includes a conductive member. The conductive member of the base 1110 can function as a lower electrode. The electrostatic chuck 1111 is placed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Another member surrounding the central region 111a of the electrostatic chuck 1111, such as an annular electrostatic chuck or an annular insulating member, may be disposed in the annular region 111b. In this case, the ring assembly 112 may be placed on one or the annular electrostatic chuck or the annular insulating member, or may be placed on both the central region 111a of the electrostatic chuck 1111 and the annular insulating member. Further, at least one RF/DC electrode connected to an RF power supply 31 and/or a power storage part 45, which will be described later, may be disposed in the ceramic member 1111a. In this case, at least one RF/DC electrode functions as a lower electrode. When a bias RF signal and/or a DC signal, which will be described later, is supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as a lower electrode. Therefore, the substrate support 11 includes at least one lower electrode.

The ring assembly 112 includes one or multiple annular members. In one embodiment, the one or multiple annular members include one or multiple edge rings and at least one cover ring. The edge ring is made of a conductive material or an insulating material, and the cover ring is made of an insulating material.

Further, the substrate support 11 may include a temperature control module configured to adjust at least one of the electrostatic chuck 1111, the ring assembly 112, and the substrate W to a target temperature. The temperature control module may include a heater, a heat transfer medium, a channel 1110a, or a combination thereof. A heat transfer fluid such as brine or a gas flows through the channel 1110a. In one embodiment, the channel 1110a is formed in the base 1110. For example, one or multiple heaters 1111c are disposed in the ceramic member 1111a of the electrostatic chuck 1111. Further, the substrate support 11 may include a heat transfer gas supply part configured to supply a heat transfer gas to the gap between the backside of the substrate W and the central region 111a.

The shower head 13 is configured to introduce at least one processing gas from the gas supply part 20 into the plasma processing space 10s. The shower head 13 has at least one gas supply port 13a, at least one gas diffusion space 13b, and a plurality of gas inlet ports 13c. The processing gas supplied to the gas supply port 13a passes through the gas diffusion space 13b and is introduced into the plasma processing space 10s from the plurality of gas inlet ports 13c. Further, the shower head 13 includes at least one upper electrode. The gas introducing part may include, in addition to the shower head 13, one or multiple side gas injectors (SGI) attached to one or multiple openings formed in the sidewall 10a.

The gas supply part 20 may include at least one gas source 21 and at least one flow rate controller 22. In one embodiment, the gas supply part 20 is configured to supply at least one processing gas from a corresponding gas source 21 to the shower head 13 via a corresponding flow rate controller 22. The flow rate controllers 22 may include, e.g., a mass flow controller or a pressure-controlled flow rate controller. Further, the supply part 20 may include one or more flow modulation devices for modulating the flow rate of at least one processing gas or causing it to pulsate.

The power supply part 30 includes an RF power supply 31 connected to the plasma processing chamber 10 via at least one impedance matching circuit. The RF power supply 31 is configured to supply at least one RF signal (RF power) to at least one lower electrode and/or at least one upper electrode. Accordingly, plasma is generated from at least one processing gas supplied to the plasma processing space 10s. Hence, the RF power supply 31 may function as at least a part of the plasma generator 12. Further, by supplying a bias RF signal to at least one lower electrode, a bias potential is generated at the substrate W, and ion components in the generated plasma can be attracted to the substrate W.

In one embodiment, the RF power supply 31 includes a first RF generator 31a and a second RF generator 31b. The first RF generator 31a is connected to at least one lower electrode and/or at least one upper electrode via at least one impedance matching circuit, and is configured to generate a source RF signal (RF source power) for plasma generation. In one embodiment, the source RF signal has a frequency within a range of 10 MHz to 150 MHZ. In one embodiment, the first RF generator 31a may be configured to generate multiple source RF signals having different frequencies. The generated one or multiple source RF signals are supplied to at least one lower electrode and/or at least one upper electrode.

The second RF generator 31b is connected to at least one upper electrode via at least one impedance matching circuit, and is configured to generate a bias RF signal (RF bias power). The frequency of the bias RF signal may be the same as or different from the frequency of the source RF signal. In one embodiment, the bias RF signal has a frequency lower than that of the source RF signal. In one embodiment, the bias RF signal has a frequency within a range of 100 kHz to 60 MHz. In one embodiment, the second RF generator 31b may be configured to generate multiple bias RF signals having different frequencies. The generated one or multiple bias RF signals are supplied to at least one lower electrode. Further, in various embodiments, at least one of the source RF signal and the bias RF signal may pulsate.

The exhaust system 40 may be connected to a gas exhaust port 10e disposed at the bottom portion of the plasma processing chamber 10, for example. The exhaust system 40 may include a pressure control valve and a vacuum pump. The pressure in the plasma processing space 10s is adjusted by the pressure control valve. The vacuum pump may include a turbo molecular pump, a dry pump, or a combination thereof.

The heater 1111c generates heat when a DC power is supplied. The DC power is supplied from the power storage part 45 to the heater 1111c.

### <Substrate Processing System>

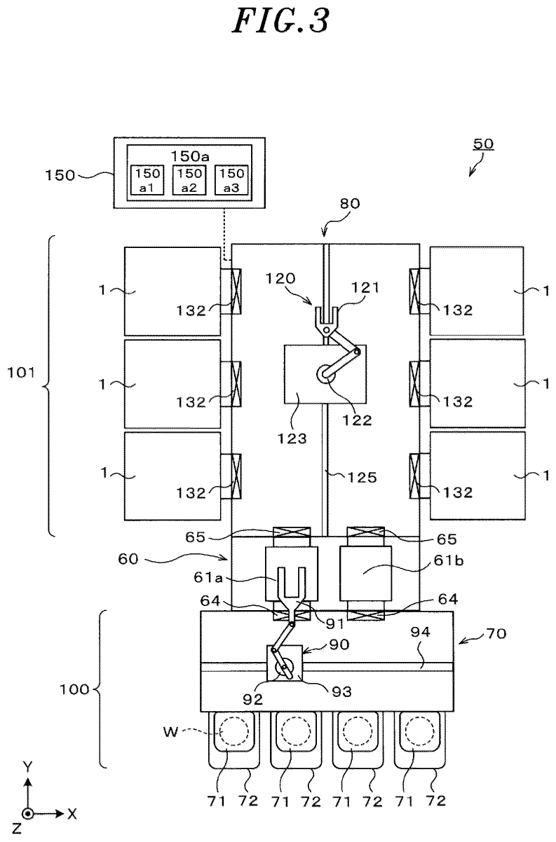

Next, a substrate processing system, which is an example of a specific configuration of a plasma processing system including the plasma processing apparatus 1 described above, will be described. FIG. 3 is a plan view schematically showing the configuration of the substrate processing system 50. In the present embodiment, a case where the substrate processing system 50 includes the plasma processing apparatus 1 for performing plasma processing such as etching, film forming, and the like on the substrate W at a plurality of locations (six locations) will be described. However, the module configuration of the substrate processing system 50 of the present disclosure is not limited thereto.

As shown in FIG. 3, the substrate processing system 50 has a configuration in which an atmospheric part 100 and a depressurization part 101 are integrally connected via a load-lock module 60. The depressurization part 101 includes a depressurization module for performing desired processing on the substrate W in a depressurized atmosphere.

The load-lock module 60 has a plurality of load-locks, e.g., two load-locks 61a and 61b in the present embodiment, arranged along the width direction (the X-axis direction) of a loader module 70 to be described later. The load-locks 61a and 61b (hereinafter, may be collectively simply referred to as “load-lock 61”) are configured to allow the inner space of the loader module 70 (to be described later) of the atmospheric part 100 and the inner space of a transfer module 80 (to be described later) of the depressurization part 101 communicate with each other through substrate transfer ports. Further, the substrate transfer ports are configured to be opened and closed by gate valves 64 and 65.

The load-lock 61 is configured to temporarily hold the substrate W. Further, the load-lock 61 is configured such that the inner atmosphere thereof can be switched between an atmospheric atmosphere and a depressurized atmosphere (vacuum state). In other words, the load-lock module 60 is configured to appropriately transfer the substrate W between the atmospheric part 100 maintained in an atmospheric atmosphere and the depressurization part 101 maintained in a depressurized atmosphere.

The atmospheric part 100 has the loader module 70 provided with a substrate transfer device 90 to be described later, and a load port 72 on which a FOUP 71 capable of storing a plurality of substrates W is placed. An orienter module (not shown) for adjusting the horizontal direction of the substrate W, or a storage module (not shown) that stores a plurality of substrates W may be disposed adjacent to the loader module 70.

The loader module 70 has a rectangular housing therein, and the housing is maintained in an atmospheric atmosphere. A plurality of, e.g., four load ports 72 are arranged side by side on one side surface constituting the longitudinal side in a negative direction of the Y-axis of the loader module 70. The load-locks 61a and 61b of the load-lock module 60 are arranged side by side on the other side surface constituting the longitudinal side in a positive direction of the Y-axis positive of the loader module 70.

The substrate transfer device 90 for transferring the substrate W is disposed in the loader module 70. The substrate transfer device 90 includes a transfer arm 91 for holding and moving the substrate W, a rotatable table 92 for rotatably supporting the transfer arm 91, and a rotatable base 93 on which the rotatable table 92 is placed. Further, a guide rail 94 extending in the longitudinal direction (X-axis direction) of the loader module 70 is disposed in the loader module 70. The rotatable base 93 is disposed on the guide rail 94, and the substrate transfer device 90 is configured to be movable along the guide rail 94.

The depressurization part 101 includes a transfer module 80 in which the substrate W is transferred, and a processing module (corresponding to the plasma processing apparatus 1 described above) for performing desired processing on the substrate W transferred from the transfer module 80. The inner atmospheres of the transfer module 80 and the processing module can be maintained in a depressurized atmosphere. In the present embodiment, a plurality of processing, e.g., six processing modules are connected to one transfer module 80. Further, the number and arrangement of the processing modules are not limited to those in the present embodiment.

The transfer module 80 as a vacuum transfer module is connected to the load-lock module 60. For example, the transfer module 80 transfers the substrate W loaded into the load-lock 61a of the load-lock module 60 to one processing module so that the substrate W is subjected to desired processing, and transfers the substrate W to the atmospheric part 100 via the load-lock 61b of the load-lock module 60. In one embodiment, the transfer module 80 has a vacuum transfer space and an opening. The opening communicates with the vacuum transfer space.

A substrate transfer device 120 as a device for transferring the substrate W is disposed in the transfer module 80. In other words, the substrate transfer device 120 is disposed in the vacuum transfer space of the vacuum transfer module. The substrate transfer device 120 includes a transfer arm 121 for holding and moving the substrate W, a rotatable table 122 for rotatably supporting the transfer arm 121, and a rotatable base 123 on which the rotatable table 122 is placed. The rotatable base 123 is disposed on a guide rail 125 extending in the longitudinal direction (Y-axis direction) of the transfer module 80, and the substrate transfer device 120 is configured to be movable along the guide rail 125.

The processing module (the plasma processing apparatus 1) performs etching or film formation on the substrate W, for example. A module for performing processing suitable for the purpose of substrate processing can be selected as the processing module. Further, the processing module communicates with the transfer module 80 via the substrate transfer port formed on the sidewall surface of the transfer module 80, and the substrate transfer port is configured to be openable and closable by a gate valve 132.

The above-described substrate processing system 50 includes a controller 150 as shown in FIG. 3. Similarly to the controller 2 described above, the controller 150 can be configured to control individual components of the substrate processing system 50 to execute various steps described herein. In one embodiment, the controller 150 may be partially or entirely included in the substrate processing system 50. For example, similarly to the controller 2, the controller 150 may include a processing part 150a1, a storage part 150a2, and a communication interface 150a3. The controller 150 is realized by, e.g., a computer 150a. The processing part 150a1 may be configured to read a program from the storage part 150a2 and perform various control operations by executing the read program. The program may be stored in advance in the storage part 150a2, or may be acquired via a medium when necessary. Further, the program may be installed via a network. The acquired program is stored in the storage part 150a2, and is read out from the storage part 150a2 and executed by the processing part 150a1. The medium may be various storage media that are readable by the computer 150a, or may be a communication line connected to the communication interface 150a3. The processing part 150a1 may be a central processing unit (CPU). The storage part 150a2 may be a random access memory (RAM), a read out memory (ROM), a hard disk drive (HDD), a solid state drive (SSD), or a combination thereof. The communication interface 150a3 may communicate with the plasma processing apparatus 1 via a communication line such as a local area network (LAN) or the like.

### <Power Supply System of Substrate Processing Apparatus>

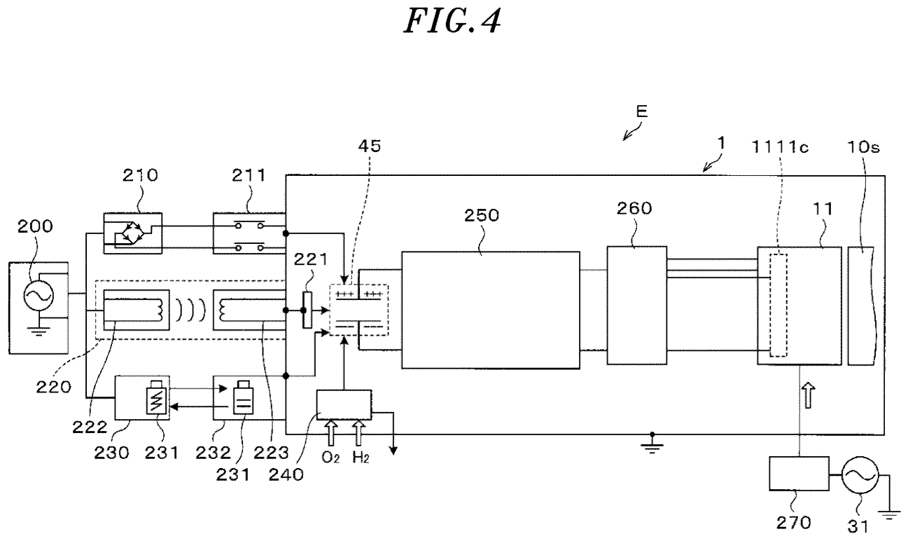

FIG. 4 is a conceptual diagram showing a schematic configuration of a power supply system E of the plasma processing apparatus 1 as a substrate processing apparatus according to an embodiment. As shown in FIG. 4, in this example, an AC power from an AC power source 200 as a factory power source (factory power supply, AC power source) is converted to a DC power, and the DC power is supplied to a unit using a DC power, for example, a heater 1111c as a member, via the power storage part 45. The heater 1111c is one or more heaters disposed in the electrostatic chuck 1111. The power storage part 45 may be one capable of storing the supplied DC power, and may be, e.g., a capacitor element or a battery. Both a capacitor element and a battery may be used together. Further, the internal (parasitic) resistance of the capacitor element is preferably small because it reduces power loss, and is, e.g., 100 mΩ or less. When a power is supplied to a plurality of heaters, an RF filter for each heater is not required in this configuration.

In the example shown in FIG. 4, four supply systems for supplying a DC power to the power storage part 45 are provided. First, in the first supply system, an AC power is supplied from the AC power supply 200 to an AC/DC converter 210. Then, the AC power is converted to a DC power, and the DC power is supplied to the power storage part 45 via a relay 211.

In the second supply system, an AC power from the AC power supply 200 passes through a wireless power supply part 220 and a DC power is supplied from an AC/DC converter 221 to the power storage part 45. In other words, the wireless power supply part 220 includes a power transmitting coil 222 to which an AC power from the AC power supply 200 is supplied, and a power receiving coil 223 disposed to oppose the power transmitting coil 222. When the AC power is supplied to the power transmitting coil 222, the AC power is outputted from the power receiving coil 223 in a non-contact manner, e.g., by a magnetic field resonance method, an electromagnetic coupling method, an electromagnetic induction method, or the like. The power transmitting coil 222 and the power receiving coil 223 are physically separated. The separation distance may be a distance at which the propagation of RF noise is suppressed and the power can be supplied. For example, the separation distance may be 1 mm or more and 200 mm or less, preferably 5 mm or more and 150 mm or less, and more preferably 10 mm or more and 100 mm or less. The AC power from the power receiving coil 223 is converted to a DC power by the AC/DC converter 221, and then the DC power is supplied to the power storage part 45.

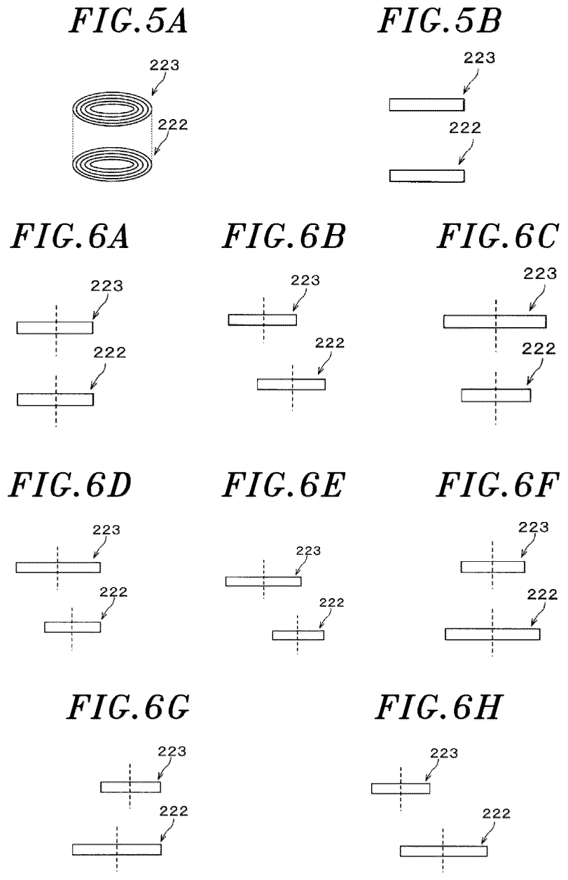

FIGS. 5A and 5B are schematic explanatory diagrams of the arrangement relationship between the power transmitting coil 222 and the power receiving coil 223. FIG. 5A is a perspective view and FIG. 5B is a side view. As shown in FIGS. 5A and 5B, a state in which the power transmitting coil 222 and the power receiving coil 223 “oppose” indicates the arrangement relationship in which the opposing surfaces of the coils are located substantially parallel to each other. For example, the separation distance is the distance between the opposing surfaces of two coils shown in FIG. 5B.

Here, the state in which the two coils “oppose” indicates the arrangement relationship in which the opposing surfaces of the coils are located parallel to each other. Further, it is unnecessary the coils have the same size. FIGS. 6A to 6H are schematic explanatory diagrams of the opposing relationship between the coils, e.g., the power transmitting coil 222 and the power receiving coil 223, and illustrate examples thereof. In FIGS. 6A to 6H, the coil center axis is indicated by dashed lines. As shown in FIGS. 6A to 6H, the power transmitting coil 222 and the power receiving coil 223 may have various configurations. For example, two coils have the same size as shown in FIGS. 6A and 6B. In plan view, FIG. 6A shows a configuration in which the entire opposing surfaces overlap and the central axes of the coils substantially coincide with each other, and FIG. 6B shows a configuration in which the opposing surfaces partially overlap. As shown in FIGS. 6C to 6E, between the two coils, the power receiving coil 223 is larger than the power transmitting coil 222. In plan view, FIG. 6C shows a configuration in which the entire opposing surface of the power transmitting coil is within the opposing surface of the power receiving coil, and the central axes of the coils substantially coincide with each other, FIG. 6D shows a configuration in which the entire opposing surface of the power transmitting coil is within the opposing surface of the power receiving coil, but the central axes of the coils do not coincide with each other, and FIG. 6E shows a configuration in which a part of the opposing surface of the power receiving coil is outside the opposing surface of the power transmitting coil. Further, as shown in FIGS. 6F to 6F, between the two coils, the power transmitting coil 222 is larger than the power receiving coil 223. In plan view, FIG. 6F shows a configuration in which the entire opposing surface of the power receiving coil is within the opposing surface of the power transmitting coil, and the central axes of the coils substantially coincide with each other, FIG. 6G shows a configuration in which the entire opposing surface of the power transmitting coil is within the opposing surface of the power receiving coil, but the central axes of the coils do not coincide with each other, and FIG. 6H shows a configuration in which a part of the opposing surface of the power receiving coil is outside the opposing surface of the power transmitting coil. Although any of the configurations (a) to (h) can be adopted, in view of power transmission efficiency, it is preferable to adopt the arrangement relationship in which the opposing surfaces of the two coils entirely overlap in plan view and the central axes of the coil substantially coincide with each other, as shown in FIGS. 6A, 6C, and 6F.

In the third supply system, an AC power is supplied from the AC power supply 200 to a charging part 230. Then, the AC power is converted to a DC power by an AC/DC converter (not shown) in the charging part 230. Then, a rechargeable battery 231 is charged, and the recharged battery 231 is set in the output part 232. Then, the DC power is supplied from the output part 232 to the power storage part 45.

In the fourth supply system, a DC power generated from a fuel cell 240 is supplied to the power storage part 45. As for oxygen and hydrogen that are raw materials of the fuel cell 240, it is possible to use, e.g., oxygen and hydrogen supplied to various semiconductor manufacturing devices in a facility where the plasma processing apparatus 1 is installed, such as a clean room. Further, the fuel cell 240 may be disposed in the plasma processing apparatus 1.

The charges stored by the DC power in the power storage part 45 are supplied, as the DC power, to a constant voltage controller 260 via a voltage control converter 250 for adjusting a DC voltage. The DC power from the constant voltage controller 260 is supplied to the heater 1111c disposed in the substrate support 11. Further, a DC/AC converter may be connected to the output side of the power storage part 45 to supply an AC power to a member that requires an AC power. In this case, the AC power received by the power receiving coil 223 and the AC power outputted by the DC/AC converter may have the same frequency or different frequencies.

The RF power from the RF power supply 31 described above is supplied to the substrate support 11 including the lower electrode via a matching box 270.

### <Effects of the Technique of the Present Disclosure>

In the plasma processing apparatus 1 according to the present embodiment, the charges stored in the power storage part 45 are supplied, as a DC power, to the heater 1111c that operates using a DC power, so that the propagation of the RF noise generated during plasma processing to the power supply system can be easily suppressed without using an RF filter.

In other words, during the plasma processing, the RF noise generated from the RF power supply 31 propagates from the substrate support 11 electrically connected to the RF power supply 31 via the heater 1111c, the constant voltage controller 260, the voltage control converter 250, and the power storage part 45.

Since, however, the DC power is supplied from the power storage part 45 to the heater 1111c, it is unnecessary to directly connect the power storage part 45 to another power source, e.g., the AC power source 200 even while the heater 1111c is operating during plasma processing. Therefore, a device for suppressing propagation of the RF noise to the AC power supply 200 can be easily adopted.

In other words, in the first supply system, the power storage part 45 and the AC power source 200 are connected via the relay 211, so that the propagation of the RF noise to the AC power supply 200 can be suppressed by cutting off the relay 211 during plasma processing. While plasma processing is not being performed, charges may be supplied to the power storage part 45 by electrically connecting the relay 211.

In the second supply system, an AC power supplied from the AC power supply 200 passes through the wireless power supply part 220 and a DC power is supplied to the power storage part 45, so that the propagation of the RF noise from the power receiving part to the power transmitting part is suppressed.

In the third supply system, the DC power from the rechargeable battery 231 is supplied to the power storage part 45, so that there is no need to consider the propagation of the RF noise from the power storage part 45 to the AC power source 200.

In the fourth supply system, the DC power generated from the fuel cell 240 is supplied to the power storage part 45, so that there is no need to consider the propagation of the RF noise from the power storage part 45 to the AC power supply 200.

Since the DC power is supplied from the power storage part 45, it is possible to easily adopt a plurality of devices for suppressing propagation of RF noise to the AC power supply 200 without using an RF filter, as shown in the first to fourth supply systems.

Further, it is unnecessary to provide an RF filter for suppressing propagation of RF noise to the AC power supply 200 in the power supply path from the power storage part 45 to the heater 1111c, so that the power can be efficiently inputted from the power storage part 45 to the heater 1111c. Moreover, since it is unnecessary to provide a filter for blocking RF noise, it is possible to suppress non-uniform processing due to variation in the filter performance, and also possible to ensure uniformity.

In the above-described embodiment, the configuration including all the first to fourth supply systems is adopted. However, the configuration including at least one of the four supply systems may be adopted.

Further, in the case of adopting a combination of a plurality of supply systems, the duration of the power storage part 45 can be extended by charging the battery 231 during plasma processing or supplying a DC power to the power storage part 45 using the fuel cell 240.

Further, as for oxygen and hydrogen that are raw materials of the fuel cell 240, it is possible to use, e.g., oxygen and hydrogen supplied to various semiconductor manufacturing devices in a facility where the plasma processing apparatus 1 is installed, such as a clean room.

Further, it should be noted that the embodiments of the present disclosure are illustrative in all respects and are not restrictive. The above-described embodiments may be omitted, replaced, or changed in various forms without departing from the scope of the appended claims and the gist thereof.

For example, in the plasma processing apparatus 1 described in the above embodiment, the DC power is supplied from the power storage part 45 to the heater 1111c, but a demand part that is supplied with a DC power from the power storage part 45 is not limited thereto. In other words, the technique of the present disclosure may be applied to any unit or any member that uses a DC power in a substrate processing apparatus or a substrate processing system.

In other words, in the present disclosure, a unit that is a combination of a plurality of members, and the unit and the member may be provided inside the substrate processing apparatus or may be provided outside the substrate processing apparatus. For example, the member provided inside the plasma processing apparatus 1 may be the base 1110 or the electrostatic chuck 1111, and the unit provided inside the plasma processing apparatus 1 may be the main body 111 or the substrate support 11. The member provided outside the plasma processing apparatus 1 may be the transfer arm 91, and the unit provided outside the plasma processing apparatus 1 may be the substrate transfer device 90.

The target member of the present disclosure may be any member that operates using a DC power or an AC power. Hereinafter, a specific example thereof will be described. For example, the following members are examples of the members constituting the plasma processing chamber 10 or neighboring members thereof. It may be a matcher electrically connected to an ICP antenna, a variable capacitor attached to an absorption coil, a motor for driving a gap between an upper electrode and a lower electrode, or the ICP antenna. Further, it may be an upper electrode, an upper RF matcher, or an upper electrode attracting mechanism. Further, it may be an electrode included in an electrostatic chuck, an actuator for driving a lift pin, a lower RF matcher, a DC pulse electrode, a cooling fan and a controller for a resistance heater, an inductive heater, a ceramic member attracting mechanism for replacing a ceramic member, or a stage driving motor. Further, it may be an edge ring, a power supply for controlling a potential of an edge ring, an edge ring driving pin, an electrode for attracting a substrate or an edge ring, a variable capacitor for impedance control, a variable inductor, a variable resistor, a relay motor, a coil, or a DC electrode. Further, it may be a resistance heater disposed on a sidewall of a chamber, a controller for a resistance heater, a DC electrode disposed on a sidewall of a chamber, or an inductive heater. Further, it may be a distance sensor, a film thickness sensor, a camera, a wafer-embedded sensor, a light emitting sensor, or a quadrupole mass spectrometer (Q-MASS), which are included in a sensor. Further, it may be a controller for an external coil (electromagnet), or a controller for an internal coil. Further, it may be a resistance heater, an inductive heater, a gas valve, or a flow rate controller, which are included in a gas box. Further, it may be a motor for a pressure control valve, a turbo molecular pump, a dry pump, or a resistance heater and an inductive heater in a line.

Further, the following members may be examples of the member located on the upstream side of the plasma processing chamber 10. It may be an AC power box, a gas box, or a chiller. Further, it may be a transfer arm for a transfer module, a sensor, a turbo molecular pump, a dry pump, a motor for a driving pin in a load-lock module, a heater, a position sensor, an arm motor, an orienter motor, a valve for circulating N₂, a motor for a shutter of a load port, a sensor, or an N₂ valve for purge storage.

Although the embodiment has illustrated and described the case where the voltage control converter 250 or the constant voltage controller 260 is included, they are not necessarily included. In other words, in one embodiment, if a member to which a power is supplied is a member that does not require voltage control, the device configuration that does not include the voltage control converter 250 or the constant voltage controller 260 may be adopted.

### Other Embodiments of the Present Disclosure

The AC power supplied from the AC power supply 200 can be efficiently transmitted when it is supplied after the frequency thereof is converted to an appropriate frequency as necessary.

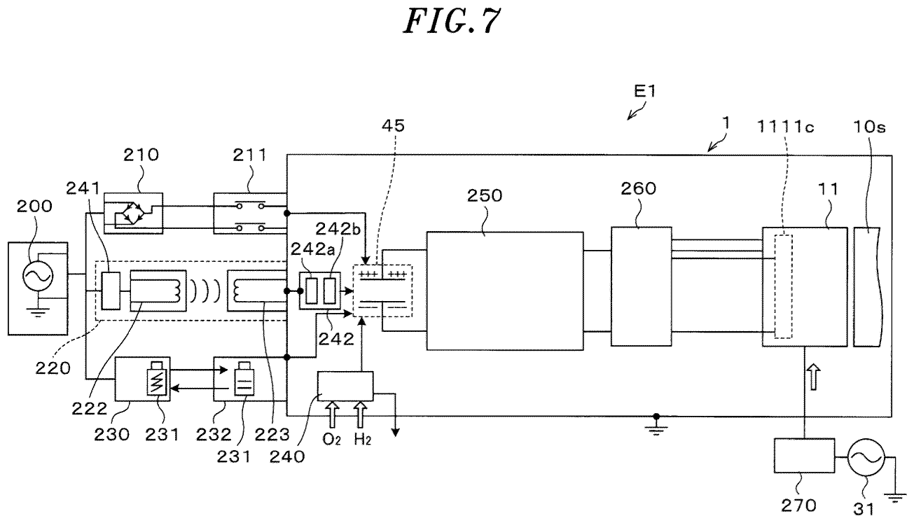

FIG. 7 is a conceptual diagram showing a schematic configuration of a power supply system E1 configured in consideration of the above-described circumstances. In FIG. 7, the members, the devices, and the like indicated by like reference numerals of FIG. 4 are the same as those of the power supply system E shown in FIG. 4, so that the redundant description thereof will be omitted.

In the power supply system E1, a frequency conversion circuit 241 is disposed between the AC power supply 200 and the power transmitting coil 222. In the frequency conversion circuit 241, the frequency of the AC power supplied from the AC power supply 200, which is 50 Hz or 60 Hz, is converted to a transmission frequency of a sine wave or a square wave, which is within a range of 85 kHz to 250 kHz, for example. When a sine wave is converted to a square wave, a sine wave converted by the frequency conversion circuit is converted to a square wave by a conversion circuit (not shown).

With such a configuration, when an AC power is transmitted from the power transmitting coil 222 to the power receiving coil 223 in a non-contact manner such as a magnetic resonance method or the like, the power whose frequency is converted by the frequency conversion circuit 241 is transmitted. Accordingly, the power having a frequency suitable for transmission can be efficiently transmitted in a non-contact manner.

In the power supply system E1, a rectifying and smoothing part 242 is provided instead of the AC/DC converter 221 shown in FIG. 4. The rectifying and smoothing part 242 includes a rectifying circuit 242a and a smoothing circuit 242b. The rectifying circuit includes, e.g., a bridge diode and the like. The smoothing circuit 242b includes a low-pass filter and the like. In the example of FIG. 7, the rectifying circuit 242a rectifies an AC signal received by the power receiving coil 223 in a forward direction (positive direction) using, e.g., a bridge diode. The output signal of the rectifying circuit 242a generally has a pulsating current waveform. Therefore, the output signal of the rectifying circuit 242a is inputted to the smoothing circuit 242b, and the pulsating current waveform is converted to a DC power waveform of an appropriate voltage by a low-pass filter. In the rectifying and smoothing part 242, the power stored in the power storage part 45 may be measured, and the power transmission and reception control in the wireless power supply part 220 may be performed based on the measurement result. Further, in the rectifying circuit 242a, the AC signal received by the power receiving coil 223 may be rectified in the opposite direction (negative direction) using, e.g., a bridge diode. Further, the frequency conversion circuit 241 may also be provided in each of other power supply systems E2 to E7 to be described later. The same effect is obtained in the case of providing the rectifying and smoothing part 242 instead of the AC/DC converter 221.

When a power is supplied from the power storage part that stores charges to a member or a unit that requires a power, the amount of charges stored in the power storage part gradually decreases as the power is supplied and, thus, the output voltage becomes lower. Eventually, the voltage required for driving the member or the unit is not obtained, so that the member or the unit cannot be driven. Hence, the device that employs the member and the unit stops.

On the other hand, even if the voltage required for driving a specific member or a specific unit is not obtained, charges still remain in the power supply part, and an output voltage corresponding thereto is obtained. Therefore, it is wasteful and inefficient to supply a power to the power supply part until a desired amount of charges is obtained even though there are residual charges.

In the following embodiments, even if the amount of charges in one power supply part decreases, the power can be supplied to another member or another unit with lower rated voltages other than the specific member or the specific unit. As a result, the substrate processing apparatus can efficiently function without stopping the entire device.

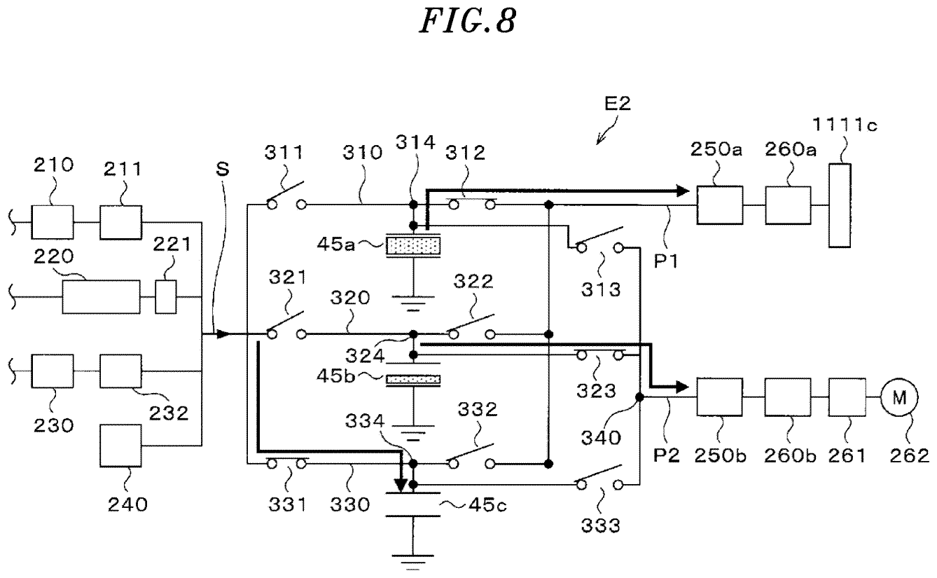

FIG. 8 schematically shows a configuration of the power supply system E2 for the plasma processing apparatus 1 configured in consideration of the above-described circumstances. In FIG. 8, the members and the components indicated by like reference numerals described in the above embodiment are the same as those in the above embodiment.

In the power supply system E2, the power storage part 45 of the above embodiment includes three power storage parts 45a, 45b, and 45c. The three power storage parts 45a, 45b, and 45c are connected in parallel. More specifically, the DC power supply system S for supplying a DC power to the power storage parts 45a, 45b, and 45c has a supply system continued from the first to fourth supply systems, as described in the above embodiment. Further, the supply system S can supply a DC power to three power supply paths 310, 320, and 330 respectively connected to the power storage parts 45a, 45b, and 45c. Further, the power storage parts 45a, 45b, and 45c are independently connected to the power supply paths 310, 320, and 330, respectively.

A relay 311 is disposed on the upstream side (closer to the supply system S) of the connection portion with the power storage part 45a in the power supply path 310, and a relay 312 is disposed on the downstream side of the connection portion in the power supply path 310 with the power storage part 45a. Similarly, a relay 321 is disposed on the upstream side (closer to the supply system S) of the connection portion with the power storage part 45b in the power supply path 320, and a relay 322 is disposed on the downstream side of the connection part with the power storage part 45b in the power supply path 320. Similarly, a relay 331 is disposed on the upstream side (closer to the supply system S) of the connection portion with the power storage part 45c in the power supply path 330, and a relay 332 is disposed on the downstream side of the connection portion with the power storage part 45c in the power supply path 330.

Further, on the downstream sides of the relays 312, 322, and 332, the power supply paths 310, 320, and 330 are connected and joined. The joined power supply path constitutes a power supply path P1 connected to the heater 1111c on the load side via the voltage control converter 250a and the constant voltage controller 260a.

On the other hand, branch points 314, 324, and 334 are disposed on the upstream sides of the relays 312, 322, and 332, which are the downstream sides of the connection portions with the power storage parts 45a, 45b, and 45c in the power supply paths 310, 320, and 330. At the branch points 314, 324, and 334, the power supply paths 310, 320, and 330 are branched, respectively. The branched power supply paths 310, 320, and 330 pass through the relays 313, 323, and 333, respectively, and then are joined at a joining point 340 to form a power supply path P2. The power supply path P2 is a power supply path connected to an AC motor 262 via a voltage control converter 250b, a constant voltage controller 260b, and a DC-AC converter 261. The AC motor 262 is driven at a lower voltage compared to the heater 1111c, and has a smaller power load compared to the heater 1111c.

As described above, the power storage parts 45a, 45b, and 45c are connected in parallel to the supply system S, and can supply a DC power for storage to the desired power storage parts 45a, 45b, and 45c by switching the relays 311, 321, and 331.

Further, the power storage parts 45a, 45b, and 45c are connected in parallel to the power supply path P1 connected to the heater 1111c and the power supply path P2 connected to the AC motor 262, and the DC power can be supplied from the desired power storage parts 45a, 45b, and 45c to the desired power supply paths P1 and P2 by switching the relays 312, 313, 322, 323, 332, and 333.

In accordance with the power supply system E2 configured as described above, the power storage part 45a, which stores a large amount of charges and can output a high DC voltage, can supply a power to the heater 1111c having a large load through the power supply path P1, and the power storage part 45b, which stores a small amount of charges compared to the power storage part 45a and cannot supply a voltage and a power required by the heater 1111c, can supply a power to the AC motor 262 that requires a low voltage and a small power for driving compared to the heater 1111c through the power supply path P2.

Specifically, the power supply from the supply system S can be stopped by switching off the relay 311, and the DC power from the power storage part 45a can be supplied to the heater 1111c by switching the relay 312 and switching off the relay 313. In the case of the power storage part 45b, the power supply from the supply system S can be stopped by switching off the relay 321, and the power can be supplied to the AC motor 262 by switching off the relay 322 and switching on the relay 323.

Further, the power storage part 45c in which a required power cannot be supplied to the AC motor 262 and other members and units of the plasma processing apparatus 1 due to a decrease in the amount of stored charges can be charged by starting the power supply from the supply system S by switching on the relay 331 and switching off the relays 332 and 333.

In accordance with the power supply system E2 adopted in the plasma processing apparatus 1 of the present embodiment, it is possible to perform switching between a high power application, a low power application, and a charge state depending on the amount of residual charges in the plurality of power storage parts 45a, 45b, and 45c, and the power storage parts 45a, 45b, and 45c can operate efficiently. The high power application may include, e.g., an increase in the temperature of the heater 1111c, and the supply of the RF power to the plasma processing chamber. The low power application may include, e.g., the power supply to the control circuit in addition to the driving of the AC motor 262. The motor is not limited to an AC motor, but may be a DC motor.

By repeating the switching operation, it is possible to prevent a high power load from concentrating on one power storage part, and the lifespan of the power storage parts 45a, 45b, and 45c can be extended.

Further, the power storage parts of which number is greater than that of loads are provided in parallel, and at least one power storage part is made to standby in a fully charged state. Accordingly, it is possible to stop an operation of a failed power storage part and immediately switch to the power storage part in a standby state. Hence, the device can operate without being stopped. Further, a charged power storage part is separately prepared to replace the failed power storage part, so that the power storage part can be replaced without stopping the device.

Further, the amount of residual charges, which is an index for switching the power storage part, is easy to measure, and can be constantly monitored by, e.g., a sensor or a voltmeter that monitors a voltage of each power storage part. Therefore, it is easy to automate the switching timing based on the signal from the sensors and the voltmeter, for example. Further, the lifespan of the power storage part can be predicted from a decrease in the amount of residual charges, so that the power storage part can be replaced before it stops functioning.

Next, other embodiments will be described. In the above-described embodiment, when a power load such as a member or a unit to which a power is supplied from the power storage part is, e.g., a plurality of heaters, a power amount required when the heaters are switched on simultaneously and a power amount required when only one heater is switched on are different. Therefore, in the case of using a high-capacity capacitor as the power storage part, the load varies considerably depending on cases. Accordingly, fast and large load variation occurs at the time of switching the number of heaters to be driven, which may result in overshoot and/or overshoot in the supply voltage waveform. If the amount of overshoot and/or undershoot is greater than a predetermined value, the operation of the member or the unit to which the power is supplied may be adversely affected. Further, when the load increases or decreases at a high speed, the power storage part may not follow the variation speed of the load, and the power supply may be delayed. For example, when the heater is ON, the supply voltage waveform does not meet the specified rise time. When the output voltage is not stable, the operation of the member or the unit to which the power is supplied is also not stable.

The embodiments to be described below are intended to suppress variation in the power even if large load variation occurs in a destination to which the power from the power storage part is supplied. Hereinafter, the other embodiments will be described with reference to the drawings.

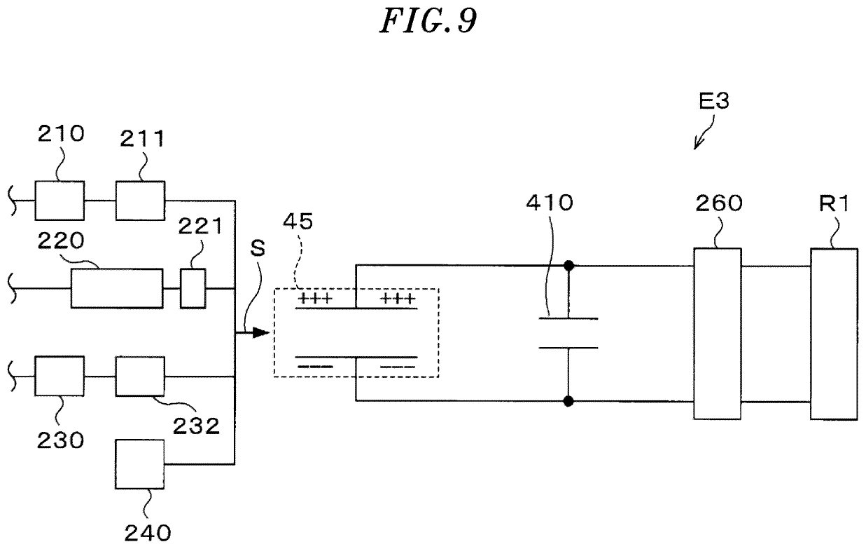

FIG. 9 schematically shows a configuration of the power supply system E3 adopted in the plasma processing apparatus 1 according to the embodiment. Further, in FIG. 9, the members and the components indicated by like reference numerals of the above embodiment are the same as those in the above embodiment.

In the power supply system E3, in addition to the power storage part 45 of the above embodiment, a relatively small-capacity power storage part 410 having a smaller capacity than that of the power storage part 45 is connected in parallel between the power storage part 45 and a power load R1 such as a member or a unit. In other words, the relatively small-capacity power storage part 410 having a smaller capacity than that of the power storage part 45 is disposed in parallel on the side close to the power load R1. In this example, the relatively small-capacity power storage part 410 and the power storage part 45 are arranged in parallel in that order from the side close to the power load R1.

The power load R1 is a load group including a plurality of members or units, and the respective loads require different powers and voltages. For example, the power load R1 includes a plurality of heaters with different rated voltage values. Therefore, each heater has a constant voltage control circuit suitable for the rated voltage. However, for convenience of illustration, the constant voltage controller 260 is illustrated as one block. Further, a constant voltage control circuit may be unnecessary depending on types of heaters.

In accordance with the power supply system E3 configured as described above, when it is possible to supply the power from the relatively small-capacity power storage part 45 to the power load R1 due to an increase or a decrease in the number of heaters to be driven by switching the number of heaters to be driven, or due to an increase or a decrease in a current value without a change in the number of heaters, the power is supplied only from the relatively small-capacity power storage part 410. On the other hand, when the power load R1 becomes large and the relatively small-capacity power storage part 410 is insufficient, the power is supplied from the power storage part 45. In other words, in order to maintain the output voltage against the load variation, insufficient charges can be supplemented sequentially from the power storage parts close to the load. Generally, the relatively small-capacity power storage part 410 has a low impedance in a relatively high frequency range, and is used for relatively high-speed charge supply. The power storage part 45 having a larger/higher capacity has a low impedance in a relatively low frequency range, and is used for relatively low-speed charge supply. Therefore, by combining the relatively small-capacity power storage part 410 and the power storage part 45 having different capacities in parallel, and arranging the relatively small-capacity power storage part 410, which has a smaller capacity and is used for a high-speed charge supply, closer to the load side, it is possible to quickly follow the output variation of the load and supply a required power. Accordingly, the change in the output voltage due to the variation in the load can be suppressed, and stable power supply can be performed.

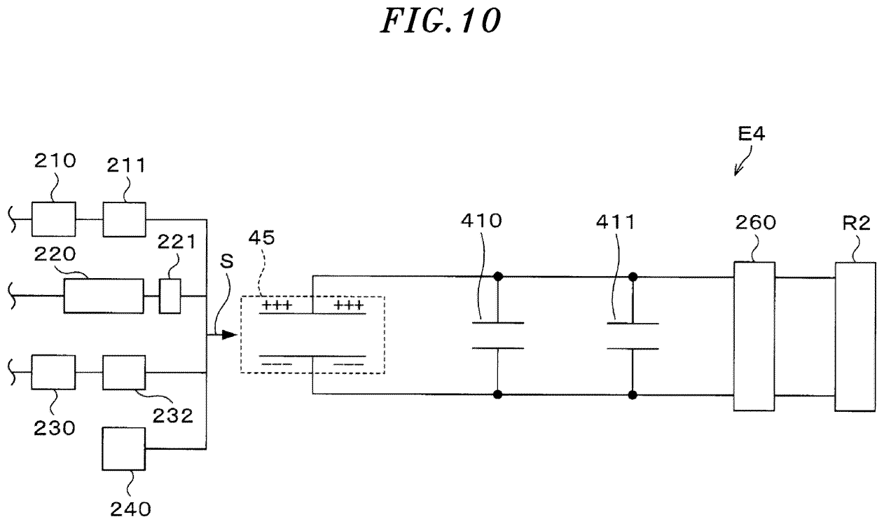

In the example shown in FIG. 9, one relatively small-capacity power storage part 410 is connected in parallel between the power storage part 45 and the power load R1 such as a member or a unit. However, as in the power supply system E4 shown in FIG. 10, another relatively small-capacity power storage part 411 having a smaller capacity than that of the relatively small-capacity power storage part 410 may be connected in parallel between the relatively small-capacity power storage part 410 and the power load R1. By adopting such a configuration, it is possible to appropriately deal with a case where there is a member or a unit having a load that requires higher load responsiveness in addition to various loads constituting the power load R1 and, thus, the output voltage for each load can become stable.

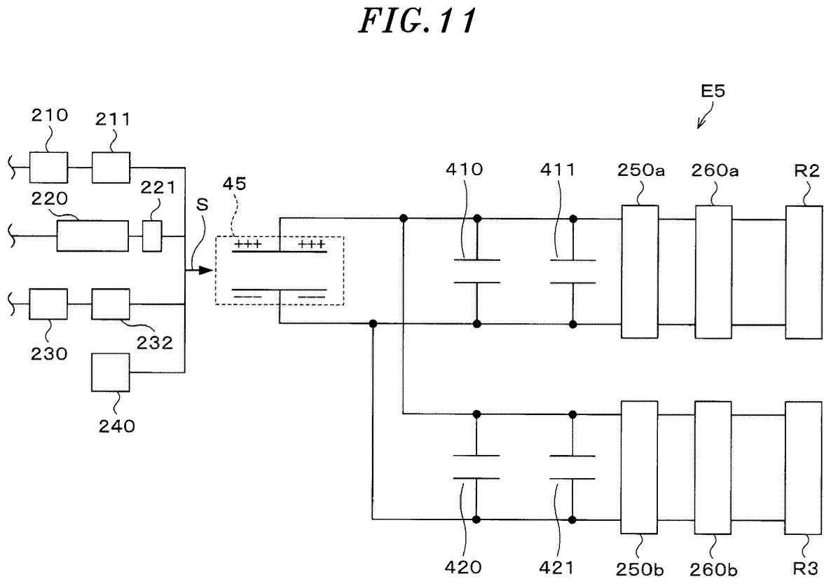

Further, in the example shown in FIG. 10, the common relatively small-capacity power storage part 410 and the relatively small-capacity power storage part 411 are connected to the power load R2. However, the configuration of the power supply system E5 shown in FIG. 11 may be adopted, for example. In other words, if there is a member or a unit having a power load smaller than the load group of the member or the unit that constitutes the power load R2, it is incorporated in the power load R2. Thus, the relatively small-capacity power storage parts 410 and 411 having lower capacities than that of the power storage part 45 are not commonly used. A small load group of such loads is set to a power load R3, and a power supply path from the relatively small-capacity power storage part 420 and the relatively small-capacity power storage part 421 that are separately provided in parallel may be provided for the power load R3.

The relatively small-capacity power storage part 420 has a smaller capacity than that of the relatively small-capacity power storage part 410, and the relatively small-capacity power storage part 421 has a smaller capacity than that of the relatively small-capacity power storage part 420. In other words, also in this example, the power storage parts having smaller capacities are connected in parallel on the side close to the power load R3.

The capacity of the relatively small-capacity power storage part disposed between the largest capacity power storage part 45 and the power load may be appropriately changed depending on the response speed of the power load. With such a configuration, it is possible to maintain a stable output voltage against the load variation over a wide range of frequency bands in response to the response speeds of various power loads such as members and units that constitute the plasma processing apparatus.

Further, in the above-described examples shown in FIGS. 9 to 11, for convenience of description and illustration, various power loads are illustrated and described as the power loads R1, R2, and R3 that are the power load groups. However, actually, the relatively small-capacity power storage parts having a small capacity are individually provided on the upstream sides (closer to the power storage part 45) of the power supply paths of the members or the units, so that the variation in the voltage can be more appropriately suppressed and the output voltage can become stable.

### Reference Example

In the substrate processing apparatus or the substrate processing system, various members are electrically connected to an external power source. Therefore, a plurality of connection wires are installed near the substrate processing apparatus or the substrate processing system. If the number of connection wires increases, mix-up of wires may occur at the time of starting or updating a device, and an operation of installing or removing wires may be complicated at the time of installing or removing a device. Further, it may be difficult to change the layout of the clean room where the substrate processing apparatus is disposed due to non-uniform lengths of power cables used as connection wires.

Further, the plasma processing apparatus as the substrate processing apparatus includes the RF power supply as the source of the RF power for generating plasma in the processing chamber. A part of the RF power applied by the RF power supply may propagate, as noise, through the connection wires. The propagated RF noise may adversely affect the operation or performance of an external power supply. The external power supply is, e.g., a factory power supply as a factory power source. Japanese Laid-open Patent Publication No. 2015-173027 discloses an RF filter that attenuates or blocks RF noise to prevent or suppress propagation of RF noise to an external power supply.

However, as described above, the increase in the number of connection wires causes a problem in the substrate processing apparatus and the substrate processing system, so that it is required to prevent mix-up of wires and simplify an operation of installing or removing wires at the time of installing or removing a device. Further, in the technique described in Japanese Laid-open Patent Publication No. 2015-173027, a filter for attenuating or blocking RF noise is required in addition to the connection wires, which may increase facility costs. Further, man-hours or costs may increase at the time of starting, installing, removing, and relocating a device, so that the decrease in the man-hours or the costs is required.

The reference technique of the present disclosure, which will be described below, has been developed in view of the above circumstances, and provides a configuration in which connection wires between a substrate processing apparatus or a substrate processing system and power facilities or neighboring connection wires are not required and the power can be transmitted. Further, the present disclosure provides a configuration capable of suppressing the influence of RF noise, which causes a problem in the plasma processing apparatus or the plasma processing system, on the factory power supply.

Hereinafter, a plasma processing apparatus as a substrate processing apparatus, a plasma processing system as a substrate processing system, and a power supply system will be described as an example of the reference technique of the present disclosure with reference to the drawings. Further, like reference numerals will be given to like parts having the same functional configurations as those in the above-described embodiments, and redundant description thereof will be omitted.

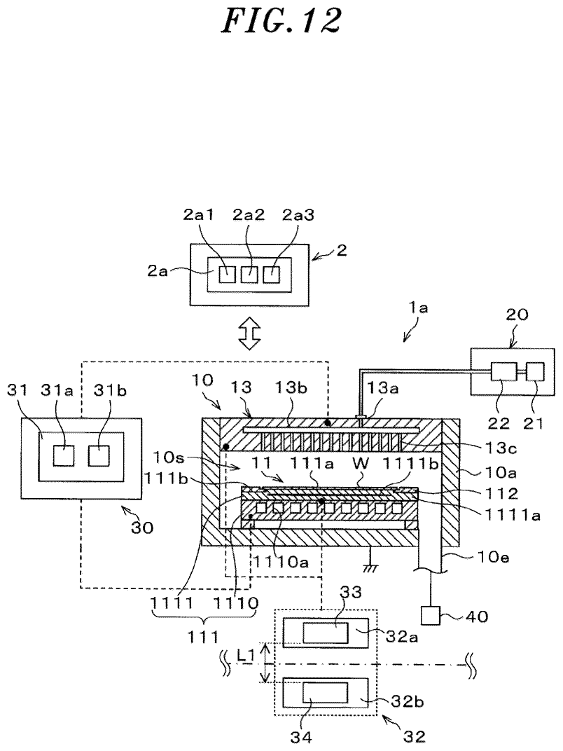

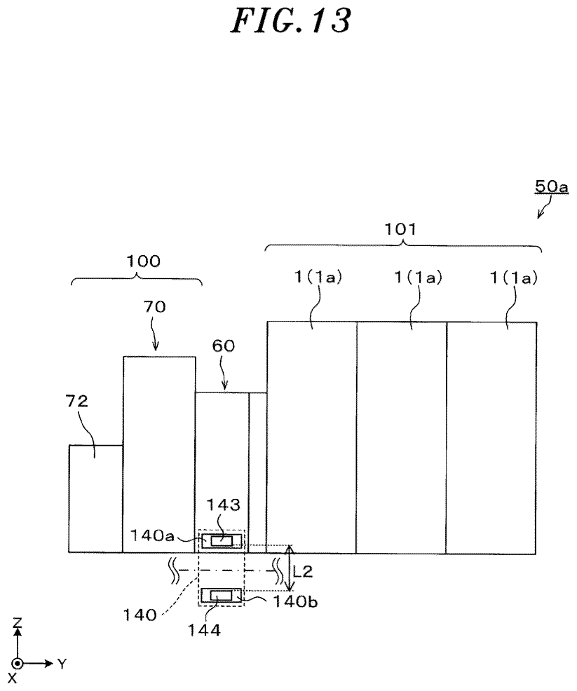

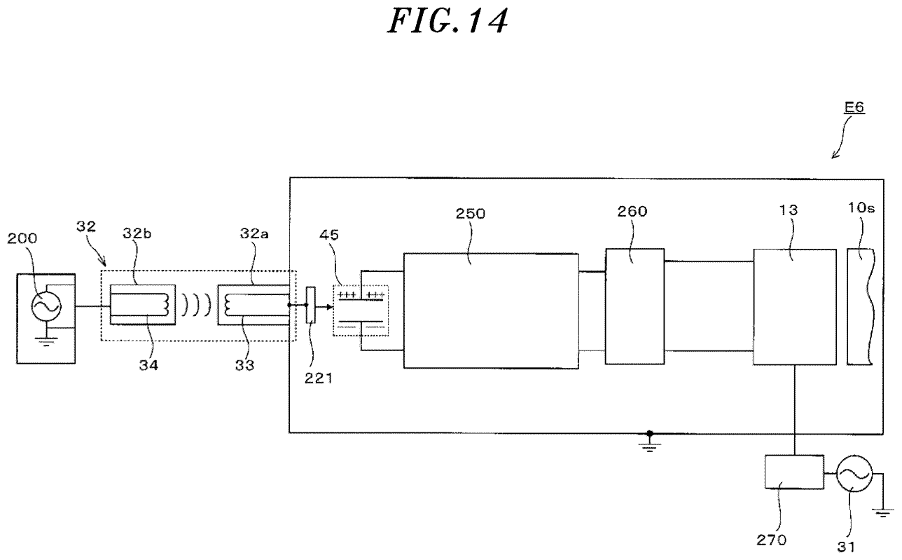

FIG. 12 is a diagram for explaining a configuration example of a capacitively coupled plasma processing apparatus 1a. FIG. 13 is a side view schematically showing a configuration of a substrate processing system 50a including the plasma processing apparatus 1a. In the plasma processing apparatus 1a, a wireless power supply part 32 that supplies a power to the plasma processing apparatus 1a is disposed in the plasma processing chamber 10. The wireless power supply part 32 includes a power receiving part 32a and a power transmitting part 32b. The power receiving part 32a includes a power receiving coil 33, and the power transmitting part 32b includes a power transmitting coil 34. The power receiving part 32a is provided inside the plasma processing apparatus 1a, the power transmitting part 32b is provided outside the plasma processing apparatus 1a. The power receiving part 32a and the power transmitting part 32b are physically separated. The power receiving part 32a is electrically connected to members provided inside the plasma processing chamber 10. The power receiving part 32a is electrically connected to at least one lower electrode and/or at least one upper electrode. The power transmitting part 32b is located outside the plasma processing apparatus 1a, and is disposed on or below the bottom surface on which the plasma processing apparatus 1a is installed. The power transmitting coil 34 and the power receiving coil 33 are physically separated. A separation distance L1 therebetween is a distance at which the propagation of RF noise can be suppressed and the power can be supplied. For example, the separation distance L1 may be 1 mm or more and 200 mm or less, preferably 5 mm or more and 150 mm or less, more preferably 10 mm or more and 100 mm or less. Further, the separation distance L1 is the distance between the opposing surfaces of the power transmitting coil 34 and the power receiving coil 33. In the wireless power supply part 32, the AC power is supplied from the AC power source to the power transmitting part 32b, and the AC power is transmitted from the power transmitting coil 34 to the power receiving coil 33 in a non-contact manner. The power transmitting part 32b may supply the AC power whose frequency has been converted by a frequency conversion circuit such as an AC/AC converter to the power receiving part 32a. The transmission method may be, e.g., a magnetic field resonance method, an electromagnetic induction method, or an electric field coupling method. Then, a conversion circuit such as an AC/DC converter (not shown) converts the AC power received by the power receiving coil 33 into a DC power, and the DC power is supplied to the members provided inside the plasma processing chamber 10. Alternatively, in one embodiment, the generated AC power may be supplied without conversion.

The power receiving part 32a may include a DC generator (not shown) that generates a DC signal. The generated DC signal may pulsate. In this case, a sequence of voltage pulses is applied to at least one lower electrode and/or at least one upper electrode. The voltage pulse may have a rectangular, trapezoidal, or triangular pulse waveform, or a combination thereof. The voltage pulse may have positive polarity or negative polarity. Further, the sequence of voltage pulses may include one or multiple positive voltage pulses and one or multiple negative voltage pulses within one cycle. In other words, the plasma processing apparatus 1a, or its constituent member, or its peripheral member includes a unit or a member that operate using a DC power.

Further, as shown in FIG. 13, a wireless power supply part 140 that supplies a power to the entire substrate processing system 50a is electrically connected to the substrate processing system 50a. The wireless power supply part 140 includes a power receiving part 140a provided on the substrate processing system 50a side, and a power transmitting part 140b provided outside the substrate processing system 50. A power receiving coil 143 in the power receiving part 140a and a power transmitting coil 144 in the power transmitting part 140b are physically separated. A separation distance L2 therebetween may be a distance at which propagation of RF noise is suppressed and a power can be supplied. For example, the separation distance L2 may be 1 mm or more and 200 mm or less, preferably 5 mm or more and 150 mm or less, and more preferably 10 mm or more and 100 mm or less.

The power receiving part 140a is disposed at an inner lower part of the load-lock module 60. The power transmitting part 140b is located below the power receiving part 140a and is disposed on or below the bottom surface on which the substrate processing system 50a is installed. The power receiving part 140a may be disposed on the side surface of the substrate processing system 50. In that case, the power transmitting part 140b may be disposed at a position corresponding to the power receiving part 140a on the side surface of the substrate processing system 50a. Although the case where the power receiving part 140a is disposed at the inner lower part of the load-lock module 60 is illustrated, the configuration of the power receiving part 140a is not limited thereto. For example, the power receiving part may be provided for each plasma processing apparatus 1a, or one power receiving part provided in the entire substrate processing system 50a may distribute a power to each plasma processing apparatus 1a.

The power receiving part 140a includes the power receiving coil 143, and the power transmitting part 140b includes the power transmitting coil 144. In the wireless power supply part 140, the AC power is supplied from the AC power source to the power transmitting part 140b, and the AC power is transmitted from the power transmitting coil 144 to the power receiving coil 143 in a non-contact manner such as a magnetic field resonance method or the like. Then, a conversion circuit such as an AC/DC converter (not shown) converts the generated AC power to a DC power, and the DC power is supplied. Alternatively, the generated AC power may be supplied without conversion.

In the plasma processing system (substrate processing system 50a), at least one of the wireless power supply part 32 described with reference to FIG. 12 and the wireless power supply part 140 described with reference to FIG. 13 may be provided, or both of them may be provided. Hereinafter, an example of a power supply system for supplying a power to the plasma processing apparatus 1a via the wireless power supply part 32 will be described with reference to the drawings.

### <Power Supply System>

FIG. 14 is a conceptual diagram showing a schematic configuration of the power supply system E6. As shown in FIG. 14, the power supply system E6 includes the AC power supply 200 as a factory power source (factory power supply, AC power source), and the power transmitting coil 34 to which the AC power is supplied from the AC power supply 200. The power transmitting coil 34 is included in the power transmitting part 32b, and the power receiving part 32a including the power receiving coil 33 is disposed to oppose the power transmitting part 32b. In the power transmitting part 32b, the AC power is transmitted from the power transmitting coil 34 to the power receiving coil 33 in a non-contact manner such as a magnetic field resonance method or the like. Accordingly, the power is transmitted from the power transmitting part 32b to the power receiving part 32a.

In this example, the power receiving part 32a is electrically connected to the power storage part 45 via an AC/DC converter 221 that is a conversion part that converts an AC power to a DC power. In other words, an AC power transmitted to the power receiving part 32a is converted to a DC power by the AC/DC converter 221, and transmitted as a DC power and stored in the power storage part 45 connected to an output side thereof. The voltage control converter 250 that adjusts a DC voltage from the power storage part 45 is connected to the output side of the power storage part 45. Further, the constant voltage controller 260 is electrically connected to the voltage control converter 250. Further, a DC/AC converter may be connected to the output side of the power storage part 45 to supply an AC power to a member that requires an AC power. In this case, the frequency of the AC power received by the power receiving part 32a and the AC power outputted by the DC/AC converter may be the same or may be different. Further, although the capacitor element 220 is illustrated as an example of a device that stores a power, a battery may be used, for example.

The shower head 13 including the upper electrode is electrically connected to the constant voltage controller 260. In other words, the power outputted from the power storage part 45 is controlled to a desired voltage by the voltage control converter 250 and controlled to a constant voltage by the constant voltage controller 260, and then is supplied to the shower head 13.

As described above, the RF power supply 31 is electrically connected to the shower head 13 including the upper electrode. The RF power supply 31 is connected to the at least one lower electrode and/or at least one upper electrode, and supplies an RF signal. Accordingly, plasma is produced from the at least one processing gas supplied to the plasma processing space 10s. One or multiple source RF signals from the RF power supply 31 are supplied to at least one lower electrode and/or at least one upper electrode via a matching box 245. Accordingly, RF noise generated from the RF power supply 31 may propagate to the power receiving part 32a via the shower head 13, the constant voltage controller 260, the voltage control converter 250, and the power storage part 45 that are electrically connected to the RF power supply 31.

In the power supply system E6, the power is supplied to the plasma processing apparatus 1a via the wireless power supply part 32, and the power is transmitted to and stored in the power storage part 45. In other words, the AC power supply 200 and the plasma processing apparatus 1a are physically separated from each other via the power receiving coil 33 and the power transmitting coil 34. The impedance between the power receiving coil 33 and the power transmitting coil 34 is set to be high for frequencies other than the frequency of the transmitted AC power. Therefore, frequencies other than the frequency of the transmitted AC power are filtered. For example, in the case of using a magnetic resonance method, the AC power has a resonance frequency. Therefore, as described above, the RF noise generated from the RF power supply 31 can be prevented from propagating to the AC power source 200. Further, the frequency of the AC power may have a predetermined bandwidth with the frequency of the AC power as the center frequency.

### Effects of Reference Example

The power supply system E6 described above adopts the configuration in which the wireless power supply part 32 including the power transmitting part 32b and a power receiving part 32a that are physically separated is used in the case of supplying a power from the AC power supply 200 to the plasma processing apparatus 1a. Similarly, the substrate processing system 50a adopts the configuration using the wireless power supply part 140 including the power transmitting part 140b and the power receiving part 140a. Therefore, the connection wires between the plasma processing apparatuses 1 and 1a or the substrate processing systems 50 and 50a and the AC power supply 200, or neighboring connection wires can be reduced or eliminated. Accordingly, mix-up of wires can be prevented, or an operation of installing or removing wires at the time of installing or removing the device can be simplified. In addition, it is possible to reduce facility costs, simplify a device design, and expand a space.

Further, in the plasma processing apparatus 1a in which the RF power supply 31 is connected to at least one lower electrode and/or at least one upper electrode, the AC power supply 200 and the plasma processing apparatus 1 are physically separated from each other to prevent RF noise from propagating to AC power supply 200. Moreover, since it is unnecessary to provide a filter for blocking RF noise, it is possible to suppress non-uniform processing due to variation in the filter performance, and also possible to ensure uniformity. In addition, the power efficiency can be improved.

Further, in the power supply system E6, when the power is supplied from the AC power source 200 to the plasma processing apparatus 1a, the power is stored in the power storage part 45, e.g., a capacitor element. Further, a member or the like that uses a DC power in the plasma processing apparatus 1a is driven by supplying charges from the capacitor element. Therefore, the amount of charges to be supplied is limited by adjusting the capacitor capacity of the capacitor element of the power storage part 45. Accordingly, it is possible to avoid an excessive current during arcing (abnormal discharge), and also possible to suppress damage to the member.

It should be noted that the above examples are illustrative, not restrictive, in all respects. The above examples may be variously omitted, replaced, and changed.

For example, in the power supply system E6, the case where the shower head 13 including an upper electrode is electrically connected to the constant voltage controller 260 is illustrated. Further, the shower head 13 including an upper electrode is illustrated as a member electrically connected to the RF power supply 31. However, the application target of the present disclosure is not limited thereto.

The DC power application, i.e., the power load, may be at least one of a substrate processing system, a substrate processing apparatus, or a unit or a member. In the present disclosure, the substrate processing system includes the plurality of substrate processing apparatuses. The substrate processing system may be the substrate processing systems 50 and 50a, and the substrate processing apparatus may be the plasma processing apparatuses 1 and 1a of present embodiment. Further, in the present disclosure, the unit is a combination of a plurality of members. The unit and the member may be provided inside the substrate processing apparatus, or may be provided outside the substrate processing apparatus. For example, the member provided inside the plasma processing apparatuses 1 and 1a may be the base 1110 or the electrostatic chuck 1111, and the unit provided inside the plasma processing apparatuses 1 and 1a may be the main body part 111 or the substrate support 11. The member provided outside the plasma processing apparatuses 1 and 1a may be the transfer arm 91, and the unit provided outside the plasma processing apparatuses 1 and 1a may be the substrate transfer device 90.

The wireless power supply of the present disclosure includes the following cases:
(1) when a power is supplied to the substrate processing system itself;
(2) when a power is supplied to the substrate processing apparatus itself;
(3) when a power is supplied to a unit provided inside the substrate processing apparatus;
(4) when a power is supplied to a member provided inside the substrate processing apparatus;
(5) when a power is supplied to a unit provided inside the substrate processing system and outside the substrate processing apparatus; and
(6) when a power is supplied to a member provided inside the substrate processing system and outside the substrate processing apparatus.

Although the case where the power supply system E6 includes the voltage control converter 250 and the constant voltage controller 260 has been illustrated and described, they are not necessarily included. In other words, if a member to which a power is supplied is a member that does not require voltage control, such as various heaters, a system configuration that does not include the voltage control converter 250 or the constant voltage controller 260 may be adopted.

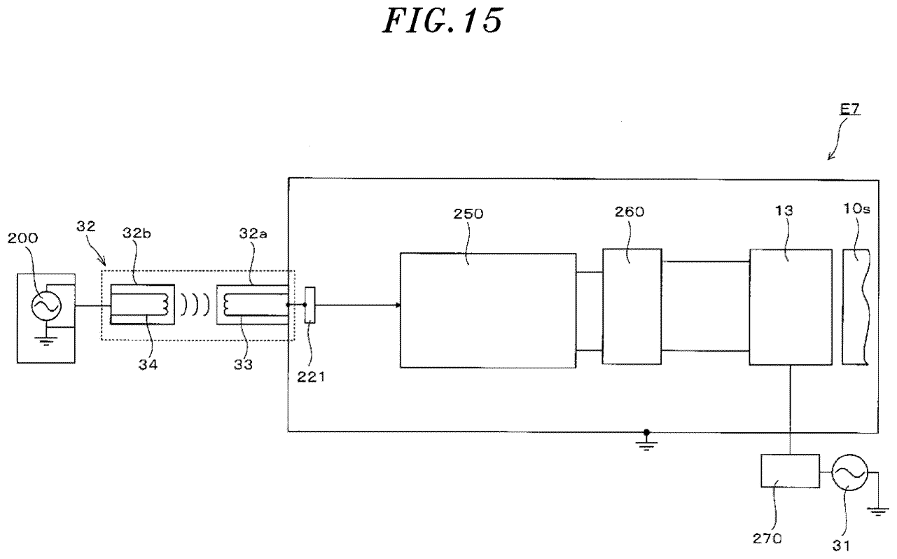

In the above reference example, in the power supply system E6, the case where the power transmitted to the power receiving part 32a passes through the AC/DC converter 210, and is transmitted to and stored in the power storage part 45 connected to the output side thereof has been illustrated and described. However, the technique of the present disclosure is not limited thereto. Hereinafter, another reference example of the present disclosure will be described with reference to FIG. 15. Further, in FIG. 15, like reference numerals will be given to like parts having the same functional configurations as those in the above-described embodiments, and redundant description thereof may be omitted.

FIG. 15 is a conceptual diagram showing a schematic configuration of the power supply system E7 according to another reference example. As shown in FIG. 15, the basic configuration of the power supply system E7 is the same as that of the power supply system E1 described above. However, the power supply system E7 has a configuration that does not include a power storage part. In other words, the power receiving part 32a of the wireless power supply part 32 is electrically connected to the voltage control converter 250 via the AC/DC converter 210.

The AC power supplied from the AC power supply 200 is transmitted to the power receiving part 32a via the power transmitting part 32b, and the power transmitted to the power receiving part 32a passes through the AC/DC converter 210 and is transmitted to the voltage controller converter 250 connected to the output side thereof. The constant voltage controller 260 is electrically connected to the voltage control converter 250. In other words, the power transmitted from the AC power supply 200 via the wireless power supply part 32 is converted to a DC power by the AC/DC converter 210, controlled to have a desired voltage by the voltage control converter 250 and controlled to have a constant voltage by the constant voltage controller 260, and then is supplied to the shower head 13.

The power supply system E7 configured as shown in FIG. 15 adopts the configuration in which the wireless power supply part 32 including the power transmitting part 32b and the power receiving part 32a that are physically separated from each other is used in the case of supplying a power from the AC power supply 200 to the plasma processing apparatus 1a. Therefore, the connection wires between the plasma processing apparatus 1a or the substrate processing system 50a and the AC power supply 200, or neighboring connection wires can be reduced or eliminated. Accordingly, mix-up of wires can be prevented, or an operation of installing or removing wires at the time of installing or removing the device can be simplified. In addition, the facility costs can be reduced, and the device space can be expanded.

Further, in the plasma processing apparatus 1a in which the RF power supply 31 is connected to at least one lower electrode and/or at least one upper electrode, RF noise can be prevented from propagating to the AC power supply 200 by physically separating the AC power supply 200 and the plasma processing apparatus 1a. Further, since it is unnecessary to provide a filter for blocking RF noise, it is possible to suppress non-uniform processing due to variation in the filter performance, and also possible to ensure uniformity. In addition, the power efficiency can be improved.

The target member of the reference example of the present disclosure may be any unit or any member in addition to the substrate processing system 50a and the plasma processing apparatus 1a that operate using a DC power or an AC power. Hereinafter, a specific example thereof will be described. For example, the following members are examples of the members constituting the plasma processing chamber 10 or neighboring members thereof. It may be a matcher electrically connected to an ICP antenna, a variable capacitor attached to an absorption coil, a motor for driving a gap between an upper electrode and a lower electrode, or the ICP antenna. Further, it may be an upper electrode, an upper RF matcher, or an upper electrode attracting mechanism. Further, it may be an electrode included in an electrostatic chuck, an actuator for driving a lift pin, a lower RF matcher, a DC pulse electrode, a cooling fan and a controller for a resistance heater, an inductive heater, a ceramic member attracting mechanism for replacing a ceramic member, or a stage driving motor. Further, it may be an edge ring, a power supply for controlling a potential of an edge ring, an edge ring driving pin, an electrode for attracting a substrate or an edge ring, a variable capacitor for impedance control, a variable inductor, a variable resistor, a relay motor, a coil, or a DC electrode. Further, it may be a resistance heater disposed on a sidewall of a chamber, a controller for a resistance heater, a DC electrode disposed on a sidewall of a chamber, or an inductive heater. Further, it may be a distance sensor, a film thickness sensor, a camera, a wafer-embedded sensor, a light emitting sensor, or a quadrupole mass spectrometer (Q-MASS). Further, it may be a controller for an external coil (electromagnet), or a controller for an internal coil. Further, it may be a resistance heater, an inductive heater, a gas valve, or a flow rate controller, which are included in a gas box. Further, it may be a motor for a pressure control valve, a turbo molecular pump, a dry pump, or a resistance heater and an inductive heater in a line.

Further, the following members may be examples of the member located on the upstream side of the plasma processing chamber 10. It may be an AC power box, a gas box, or a chiller. Further, it may be a transfer arm for a transfer module, a sensor, a turbo molecular pump, a dry pump, a motor for a driving pin in a load-lock module, a heater, a position sensor, an arm motor, an orienter motor, a valve for circulating N₂, a motor for a shutter of a load port, a sensor, or an N₂ valve for purge storage.

### APPENDICES

### Appendix 1

A substrate processing apparatus for processing a substrate, comprising:
a power receiving part including a power receiving coil to which a power is transmitted in a non-contact manner from a power transmitting coil disposed outside the substrate processing apparatus,
wherein a power is supplied to at least one unit or member that uses the power from the power receiving part.

### Appendix 2

The substrate processing apparatus of Appendix 1, wherein the unit or the member that uses the power from the power receiving part includes an upper electrode of the substrate processing apparatus.

### Appendix 3

The substrate processing apparatus of Appendix 1 or 2, wherein the unit or the member that uses the power from the power receiving part includes a lower electrode of the substrate processing apparatus.

### Appendix 4

The substrate processing apparatus of any one of Appendices 1 to 3, further comprising:
a power storage part configured to store the power supplied from the power receiving part,
wherein between the power storage part and an AC power source configured to supply a power to the power transmitting coil, an impedance of a frequency other than a frequency of the transmitted AC power is set to be higher than an impedance of the frequency of the transmitted AC power, and
a conversion part configured to convert an AC power from the power receiving coil to a DC power is connected to the power storage part.

### Appendix 5

The substrate processing apparatus of Appendix 1, further comprising:
a power storage part configured to store the power supplied from the power receiving part, wherein between the power storage part and the AC power source configured to supply a power to the power transmitting coil, the impedance of the frequency other than the frequency of the transmitted AC power is set to be higher than the impedance of the frequency of the transmitted AC power;
a frequency conversion circuit configured to convert the frequency of the power supplied from the AC power source to the power transmitting coil to a transmission frequency and transmit the power; and
a rectifier circuit and a smoothing circuit configured to rectify and smooth the power supplied from the power receiving coil to the power storage part.

### Appendix 6

The substrate processing apparatus of Appendix 4 or 5, wherein the power storage part is a capacitor element or a battery.

### Appendix 7

A substrate processing system including a plurality of substrate processing apparatuses for processing a substrate, comprising:
a power receiving part including a power receiving coil to which a power is transmitted in a non-contact manner from a power transmitting coil disposed outside the substrate processing system,
wherein a power is supplied to at least one of the substrate processing apparatus, a unit, or a member that uses the power from the power receiving part.

### Appendix 8

The substrate processing system of Appendix 7, further comprising:
a power storage part configured to store the power supplied from the power receiving part,
wherein between the power storage part and an AC power source configured to supply a power to the power transmitting coil, an impedance of a frequency other than a frequency of the transmitted AC power is set to be higher than an impedance of the frequency of the transmitted AC power, and
a conversion part configured to convert the AC power from the power receiving coil to a DC power is connected to the power storage part.

### Appendix 9

The substrate processing system of Appendix 7, comprising:
a power storage part that stores the power supplied from the power receiving part, wherein between the power storage part and an AC power source configured to supply a power to the power transmitting coil, the impedance of the frequency other than the frequency of the transmitted AC power is set to be higher than the impedance of the frequency of the transmitted AC power;
a frequency conversion circuit configured to convert the frequency of the power supplied from the AC power source to the power transmitting coil to a transmission frequency and transmit the power; and
a rectifier circuit and a smoothing circuit configured to rectify and smooth the power supplied from the power receiving coil to the power storage part.

### Appendix 10

The substrate processing system of Appendix 8 or 9, wherein the power storage part is a capacitor element or a battery.

### Appendix 11

A power supply system for supplying a power to at least one of a substrate processing system, a substrate processing apparatus, a unit, or a member that uses a power, comprising:
a power transmitting part including a power transmitting coil to which a power is supplied from an AC power source; and
a power receiving part including a power receiving coil to which a power is transmitted from the power transmitting coil in a non-contact manner,
wherein a power is supplied from the power receiving part to at least one of the substrate processing system, the substrate processing apparatus, a unit, or a member.

### Appendix 12

The power supply system of Appendix 11, further comprising:
a power storage part configured to store the power supplied from the power receiving part,
wherein between the power storage part and the AC power source configured to supply a power to the power transmitting coil, an impedance of a frequency other than a frequency of the transmitted AC power is set to be higher than an impedance of the frequency of the transmitted AC power, and
a conversion part configured to an AC power from the power receiving coil to a DC power is connected to the power storage part.

### Appendix 13

The power supply system of Appendix 11 or 12, wherein the unit or the member is included in a substrate processing system including a plurality of the units, and
the power receiving part is disposed in each of the plurality of units.

### Appendix 14

The power supply system of Appendix 13, wherein the power transmitting part is disposed on or below a bottom surface where the unit is installed.

### Appendix 15

The power supply system of Appendix 11 or 12, wherein the unit or the member is included in a substrate processing system including a plurality of the units, and
the power receiving part is disposed in the substrate processing system.

### Appendix 16

The power supply system of Appendix 15, wherein the power transmitting part is disposed on or below a bottom surface where the substrate processing system is installed.

### Appendix 17

The power supply system of Appendix 11, comprising:
a power storage part configured to store the power supplied from the power receiving part, wherein between the power storage part and the AC power source configured to supply a power to the power transmitting coil, the impedance of the frequency other than the frequency of the transmitted AC power is set to be higher than the impedance of the frequency of the transmitted AC power;
a frequency conversion circuit configured to convert the frequency of the power supplied from the AC power source to the power transmitting coil to a transmission frequency and transmit the power; and
a rectifier circuit and a smoothing circuit configured to rectify and smooth the power supplied from the power receiving coil to the power storage part.

### Appendix 18

The power supply system of Appendix 12 or 17, wherein the power storage part is a capacitor element or a battery.

### Appendix 19

A power supply method for supplying a power to at least one of a substrate processing system, a substrate processing apparatus, a unit, or a member that uses a power,
wherein a power is supplied to at least one of the substrate processing system, the substrate processing apparatus, a unit, or a member using a power supply system including a power transmitting part including a power transmitting coil to which a power is supplied from an AC power source and a power receiving part including a power receiving coil to which the power is transmitted in a non-contact manner from the power transmitting coil.

1. A substrate processing apparatus comprising:
a power storage part; and
at least one unit or member that uses a power,
wherein charges stored in the power storage part are supplied, as a power, to the unit or the member.

2. The substrate processing apparatus of claim 1, further comprising:
a power receiving coil configured to receive a power without being in contact with a power transmitting coil to which a power from an AC power source is supplied,
wherein a conversion part configured to convert an AC power from the power receiving coil to a DC power is connected to the power storage part.

3. The substrate processing apparatus of claim 1, further comprising:
a controller,
wherein the controller is configured to convert a power from an AC power source to a DC power and supply the DC power to the power storage part, and
the controller is configured to electrically cut off the power storage part and the AC power source during substrate processing using an RF power in the substrate processing apparatus.

4. The substrate processing apparatus of claim 3, wherein the controller is configured to supply a power to the power storage part through an electrical supply path after the power from the AC power source is converted to the DC power,
a relay is disposed in the electrical supply path, and
the relay is cut off during substrate processing using an RF power in the substrate processing apparatus.

5. The substrate processing apparatus of claim 2, further comprising:
a frequency conversion circuit configured to convert a frequency of the power supplied from the AC power source to a transmission frequency and transmit the corresponding power; and
a rectifier circuit and a smoothing circuit configured to rectify and smooth the power whose frequency has been converted by the frequency conversion circuit and supply the corresponding power to the power storage part.

6. The substrate processing apparatus of claim 1, wherein the power supply to the power storage part is performed by supplying a DC power from a battery.

7. The substrate processing apparatus of claim 6, wherein the battery is charged by a DC power converted from power from an AC power source.

8. The substrate processing apparatus of claim 1, further comprising:
a power generation mechanism,
wherein the power supply to the power storage part is performed by supplying a power obtained by the power generation mechanism.

9. The substrate processing apparatus of claim 8, wherein the power generation mechanism uses fuel cell power generation.

10. The substrate processing apparatus of claim 9, wherein at least one of oxygen and hydrogen used in the fuel cell power generation is used for substrate processing in a facility where the substrate processing apparatus is installed.

11. The substrate processing apparatus of claim 1, wherein a plurality of the power storage parts are provided, and the plurality of power storage parts are connected in parallel to the unit or the member, and
when a voltage of one of the plurality of power storage parts decreases and becomes lower than a voltage required for the unit or the member to which charges stored in said one power storage part is supplied as power, power supply is switched to supply from another power storage part.

12. The substrate processing apparatus of claim 11, wherein after the power supply is switched to the supply from said another power storage part, said one power storage part whose voltage has decreased supplies a power to a unit or a member that is driven even at the decreased voltage.

13. The substrate processing apparatus of claim 11, wherein after the power supply is switched to the supply from said another power storage part, a power is supplied to said one power storage part whose voltage has decreased.

14. The substrate processing of claim 1, wherein a relatively small-capacity power storage part having a smaller capacity than a capacity of the power storage part is connected in parallel between the power storage part and the unit or the member.

15. The substrate processing apparatus of claim 14, wherein another relatively small-capacity power storage part having a smaller capacity than a capacity of the relatively small-capacity power storage part is connected in parallel between the relatively small-capacity power storage part and the unit or the member.

16. The substrate processing apparatus of claim 1, wherein the power storage part is a capacitor element or a battery.

17. The substrate processing apparatus of claim 16, wherein an internal resistance of the capacitor element is 100 mΩ or less.

18. A substrate processing method for processing a substrate using a substrate processing apparatus,
wherein the substrate processing apparatus includes a power storage part and at least one unit or member that uses a power, and
charges from the power storage part are supplied as a power to the unit or the member.
